(19) United States
(12) Patent Application Publication
(10) Pub. No.: US 2019/0097106 A1
(43) Pub. Date: Mar. 28, 2019

(54) Connection Carrier, Optoelectronic Component and Method for Producing a Connection Carrier or an Optoelectronic Component

(71) Applicants: OSRAM Opto Semiconductors GmbH, Regensburg (DE); Heraeus Deutschland GmbH & Co. KG, Hanau (DE)

(72) Inventors: Eckhard Ditzel, Linsengericht (DE); Tihomir Klajic, Kahl Am Main (DE); Reiner Windisch, Pettendorf (DE); Andreas Biebersdorf, Regensburg (DE)

(21) Appl. No.: 16/081,176

(22) PCT Filed: Feb. 10, 2017
(86) PCT No.: PCT/EP2017/053030

§ 371 Date: Aug. 30, 2018

(30) Foreign Application Priority Data
Mar. 3, 2016 (DE) 10 2016 103 819.9

(51) Int. Cl. H01L 33/62; H01L 33/20; H01L 33/44; H01L 33/48; H01L 33/54; H01L 25/16; H01L 25/075; H01L 23/00

(52) U.S. Cl. CPC H01L 33/62; H01L 33/20; H01L 33/44; H01L 33/486; H01L 2224/48091; H01L 25/167; H01L 25/0753; H01L 24/49; H01L 33/54

(57) ABSTRACT

A connection carrier, an optoelectronic component and a method for producing a connection carrier or an optoelectronic component are disclosed. In an embodiment a connection carrier includes a substrate, an electrically insulating connecting element, an electrically conductive contact element and an insulation element.

This patent application is a national phase filing under section 371 of PCT/EP2017/053030, filed Feb. 10, 2017, which claims the priority of German patent application 10 2016 103 819.9, filed Mar. 3, 2016, each of which is incorporated herein by reference in its entirety.

### TECHNICAL FIELD

The documents U.S. Pat. No. 8,975,532 B2 and DE 102008044847 A1 each describe a connection carrier, an optoelectronic semiconductor component and a method for producing a connection carrier.

### BACKGROUND

One of the problems to be solved is to specify a connection carrier and an optoelectronic component, which can be produced particularly cost-effectively. Another problem to be solved is to specify a connection carrier and an optoelectronic component that can be used particularly safely.

### SUMMARY OF THE INVENTION

Embodiments provide a connection carrier. The connection carrier is, for example, a circuit board with contact elements and contact points for electrical connection and contacting. The connection carrier also serves as a mechanically supporting carrier on which electronic components, such as semiconductor chips, are arranged and fastened.

According to at least one aspect, the connection carrier comprises a substrate. The substrate has a substrate top surface formed by a principal surface of the substrate on the top side of the substrate. The substrate further has a substrate bottom surface opposite the substrate top surface and at least one substrate side surface connecting the substrate top surface to the substrate bottom surface.

The substrate top surface and the substrate bottom surface can be circular or n-angled, for example. In one aspect the substrate can be cuboid and the substrate top surface and substrate bottom surface are rectangular, in particular square. The edge length of the substrate can then, for example, be between at least 2 mm and at most 50 mm, in particular between at least 6 mm and at most 35 mm.

The substrate is the mechanically supporting component of the connection carrier. This means that the substrate is intended to mechanically support and carry the other components of the connection carrier. The substrate is mechanically self-supporting. For this purpose, the substrate can be rigid or flexible.

In addition to the mechanical supporting properties, the substrate in the connection carrier can adopt further properties. For example, the substrate can be designed to absorb or reflect light on the substrate top surface. In this case, the substrate can adopt optical properties in the connection carrier.

It is further possible that the substrate takes over electrical properties in the connection carrier. For this purpose, the substrate can, for example, be electrically conductive or electrically insulating on the substrate top surface.

The substrate has a main extension plane along which it extends in two lateral directions. For example, the main extension plane of the substrate may be parallel to or along the top and/or bottom surface of the substrate within the manufacturing tolerance. Perpendicular to the main extension plane, in a vertical direction, then runs, for example, the at least one substrate side surface. Along this direction, the substrate then has a thickness that can be particularly small against the extension of the substrate in the lateral directions.

The substrate can be a thin plate, for example, a thin carrier metal plate. For example, the substrate can have a thickness between at least 0.3 mm and at most 2.2 mm, in particular at most 1.5 mm. In particular, it is possible that the substrate has a thickness of at least 0.5 mm and at most 1.0 mm.

The substrate may contain metals or consist of metals. For example, the substrate is multilayered. The substrate can then have a base body, a dielectric layer system and optionally a metallic reflective layer. For example, an exposed outer surface of the base body can form the substrate bottom surface. Furthermore, an exposed outer surface of the dielectric layer system or the metallic reflective layer can at least partially form the substrate top surface. The base body of the substrate can, for example, be formed with a metal such as aluminum or consist of a metal. One side of the substrate body facing away from the substrate bottom surface may be band anodized and/or anodized. Optionally, the metallic reflective layer can be present there, which is formed, for example, with aluminum or silver or consists of one of these materials. A layer sequence may be provided between the base body and the metallic reflective layer, which may contain an elox layer. The elox layer can contain an oxide, especially aluminum oxide or silver oxide.

The dielectric layer system may comprise several layers, wherein at least one of the layers of the layer system may contain an oxide or consist of an oxide. For example, the layer system contains TiO₂, SiO₂, Al₂O₃, Nb₂O₅ or Ta₂O₅. The layer system can be designed in particular as a dielectric mirror, such as a Bragg mirror.

An accordingly formed connection carrier is described, for example, in the German patent application DE 10 2015 107 675.8 in another context. The disclosure content of this patent application is hereby expressly incorporated by reference in its entirety.

According to at least one aspect, the connection carrier comprises a connecting element. The connecting element is designed to be electrically insulating. The connecting element is an element by means of which components of the connection carrier are connected to each other, in particular in a material-locking manner. Here and in the following, for example, a “material-locking” connection is a connection in which the connection partners are held together by atomic and/or molecular forces. A material-locking connection is characterized, for example, by the fact that it is not detachable mechanically non-destructively. This means that at least one of the connection partners and/or the connecting element is destroyed and/or damaged during the attempt to loosen the material-locking connection by mechanical force. In particular, the connecting element is destroyed and/or damaged when attempting to loosen it.

For example, the material-locking connection is an adhesive connection, a welded connection and/or a fused connection. Furthermore, the material-locking connection can be produced by spraying and/or vapor deposition of the material of the connecting element onto at least one of the connection partners. For example, the connecting element can be an adhesive or an adhesive tape.

The connecting element may be formed in particular with an oxide, a nitride, a polymer and/or a plastic material or may consist of one of these materials. For example, the connecting element is an adhesive tape, whereby the term “tape” is not intended to describe a shape of the connecting element, but rather the connecting element can also have curved outer edges in plan view, for instance.

The connecting element may, for example, have a carrier layer consisting of PET or fluoropolymers or containing these materials. The carrier layer can be coated on both sides with an adhesive layer. The adhesive layer can be so developed that it only develops significant adhesive strength above a certain contact pressure. It can also be so developed that it can be hardened or that it loses its adhesive strength in exposed areas, for example, through plasma treatment, so that no particles adhere unintentionally to the areas of the adhesive tape that are exposed in the finished state of the substrate.

For example, the connecting element can be designed as a layer with a uniform thickness within the manufacturing tolerance. The thickness of the fastener can then, for example, be between at least 5 μm and at most 200 μm, in particular between at least 15 μm and at most 100 μm.

According to at least one aspect of the connection carrier, the connection carrier comprises a contact element which is electrically conductive. The contact element can contain at least one metal or consist of at least one metal. For example, the contact element may contain a base material that is provided with a coating. For example, the contact element may contain a base material that contains stainless steel or copper or is made of one of these materials. The coating of the base material can be formed on at least one main surface of the contact element and consist of a metal such as silver or gold or contain one of these metals on its upper side facing away from the base material. Between the coating and the base material, other materials may be introduced as adhesion promoters and/or diffusion barriers, which may contain titanium, platinum, palladium and/or nickel, for example, or consist of one of these materials.

The contact element can have a constant thickness within the manufacturing tolerance. For example, the contact element has a thickness between at least 5 μm and at most 200 μm, especially between at least 20 μm and at most 80 μm.

According to at least one aspect of the connection carrier, the connection carrier comprises an insulation element which is designed to be electrically insulating. For example, the insulation element can be a component that is constructed similar to the connecting element, whereby the insulation element only has to have adhesive or adhesive properties on one main surface and a second main surface may not be adhesive or non-adhesive. Furthermore, the insulation element can be a material that is applied by spraying and/or evaporation and/or a printing process. The insulation element can then be a lacquer layer, in particular a solder resist lacquer layer. In addition to its electrical properties as an electrically insulating component of the connection carrier, the insulation element can also perform optical tasks in the connection carrier. For this purpose, the insulation element can be black, colored or white, for example.

The use of a lacquer for the insulation element also proves to be advantageous, as in this way the insulation element can also cover the side of the connecting element facing the central region, which considerably reduces the stress on the connecting element, in particular with blue light or UV radiation, and thus improves the aging stability of the connecting element.

According to at least one aspect of the connection carrier, the connecting element is arranged on the substrate top surface, the contact element is arranged on the side of the connecting element facing away from the substrate and the insulation element is arranged on the side of the contact element facing away from the connecting element. The components of the connection carrier, i.e., the substrate, the connecting element, the contact element and the insulation element, can be connected to each other in a material-locking manner. In particular, the connecting element provides a material-locking connection between the substrate and the contact element.

According to at least one aspect of the connection carrier, the insulation element covers the contact element on a contact element cover surface facing away from the connecting element and on a contact side surface facing the substrate side surface. In particular, it is possible that the insulation element extends from the contact element cover surface to the contact element side surface without interruption. Contact element side surfaces not facing the substrate side surface can remain free of the insulation element. However, it is also possible that contact element side surfaces not facing the substrate side surface are at least partially covered by the insulation element. In particular, however, all contact element side surfaces facing the substrate side surface are completely covered by the insulation element. On the other hand, the contact element cover surface is partially free of the insulation element and only regionally covered by the insulation element. By means of the insulation element it is possible to electrically insulate the contact element, especially at the outer edges of the connection carrier, whereby creepage distances at the outer edges of the connection carrier can be avoided.

According to at least one aspect of the connection carrier, the substrate top surface is freely accessible in a central region. This means that at least in the central region of the substrate top surface, there is no other component of the connection carrier, such as the connecting element, the contact element, the insulation element, and the substrate top surface is not covered by these components. In this way, the substrate top surface is freely accessible and can serve, for example, as a mounting surface for semiconductor components that are to be attached to the connection carrier and electrically connected. The semiconductor devices can then be in direct contact with the substrate, for example, or only a connection means is arranged between the substrate and the semiconductor device.

According to at least one aspect of the connection carrier, the central region is surrounded laterally by the insulation element. This means that the insulation element is arranged laterally spaced from the central region in at least one direction. In particular, it is possible that the insulation element partly or completely surrounds the central region laterally. The insulation element can be spaced from the central region, so that other components of the connection carrier are arranged at least partially between the central region and the insulation element. The insulation element serves to avoid creepage distances at the outer edges of the connection carrier. This can be achieved particularly efficiently because the central region is surrounded laterally by the insulation element.

In other words, the side surface of the contact element and/or the connecting element facing away from the central region is covered by the insulation element. By means of the insulation element, the outer edges of the connection carrier in particular can therefore be electrically insulatable.

According to at least one design of the connection carrier, a connection carrier is specified with a substrate comprising a substrate top surface, a substrate bottom surface opposite the substrate top surface and a substrate side surface, a connecting element that is electrically insulating, a contact element which is electrically conductive, and an insulation element which is electrically insulating, wherein the connecting element is arranged on the substrate top surface, the contact element is located on the side of the connecting element remote from the substrate, the insulation element is arranged on the side of the contact element facing away from the connecting element, the substrate side surface connects the substrate top surface and the substrate bottom surface, the insulation element covers the contact element on a contact element cover surface facing away from the connecting element and on a contact element side surface facing the substrate side surface, the substrate top surface is freely accessible in a central region, and the central region is surrounded laterally by the insulation element.

In this case, the connection carrier can comprise exactly one connecting element on which the contact element is arranged or the connection carrier comprises two or more connecting elements on which two or more contact elements are arranged.

In particular, it is possible that the described components of the connection carrier adjoin each other directly, i.e., the connecting element adjoins directly the substrate, the contact element adjoins directly the connecting element and the insulation element adjoins directly at least the contact element, if necessary also directly the connecting element and/or the substrate. The connection between these components can be a material-locking connection. This enables particularly safe electrical insulation of the contact element at least at the outer edges of the connection carrier. The connection carrier can then consist of the components mentioned. This means that the connection carrier then consists of the substrate, the connecting element, the contact element and the insulation element, whereby the connecting element, contact element and insulation element can be present in the singular or in the plural.

Furthermore, it is possible that two or more contact elements are arranged on exactly one connecting element, whereby there may be areas between the contact elements where the connecting element cover surface facing away from the substrate is free of contact elements. The connection carrier preferably comprises at least two electrically isolated contact elements, which are electrically isolated from each other by the connecting element and, if necessary, the insulation element. The two or more contact elements can be used to connect components that are to be attached and contacted to the connection carrier in an electrically conductive manner.

A connection carrier described here is based on the following considerations, among others:

One way of forming a connection carrier is to apply a printed circuit board (PCB) to a highly reflective substrate, for example, comprising an aluminum carrier plate with a reflective silver mirror, on the top side, in which areas for mounting light-emitting components, for example, are omitted. Another possibility is to use as substrate a particularly white ceramic material on which metallization is applied, which serve as conductor paths for connecting components. However, the connection carriers mentioned are relatively expensive to produce. Compared to such connection carriers, a connection carrier described here is therefore characterized by particularly low production costs.

Furthermore, a connection carrier described here can have further characteristics that distinguish it from the aforementioned connection carriers. For example, it is possible that two opposite quadrants of the connection carrier, on which, for example, no contact point for contacting the connection carrier is formed, have areas that are electrically insulated, for example, because they are covered by the insulation element. These areas can be provided, for example, for hold-down devices that are used during the assembly of the connection carrier at the destination. In this way, these hold-down devices can be designed with electrically conductive structures, such as metallic retaining springs, for example. Furthermore, it is possible to provide mounting openings in these areas, for example, drilled holes, with which the connection carrier can be fastened to the destination using screws, rivets or bolts.

Furthermore, a connection carrier described here is characterized by the fact that side surfaces of the connection carrier, in particular the substrate side surfaces, can be designed as straight and/or smooth as possible without recesses. In this way, the side surfaces are available for mechanical adjustment of the orientation of the connection carrier at the destination.

Furthermore, with a connection carrier described here, it is not necessary to form the contact elements in strip form, i.e., rectangular, for example. Rather, the shape of the contact elements can be adapted in plan view to the requirements of, for example, the components to be mounted and contacted on the connection carrier. For example, a contact surface on the contact element cover surface can be optimized in shape and size for wire bond contact.

For example, it is possible to structure the connecting element and/or the contact element and/or the insulation element by a punching or laser process before applying it to the substrate. In this way, any contact or conductor track geometries can be flexibly implemented. In particular, the insulation element can then be a pre-structured insulation foil that is glued to exposed areas of the contact element that are not intended for contacting a component.

Furthermore, it is possible to place two contact elements of the connection carrier in a lateral direction so close to each other that, for example, an ESD (Electro-Static Discharge) protective element can be attached to a contact element and a wire contact can be made to the spaced contact element without having to bridge a distance between the contact elements that is too long for the wire contact.

Moreover, it is possible to attach the contact elements to a connection carrier described here in such a way that sufficient space is available between the contact element and the outer edge of the connection carrier to electrically insulate the area of the contact element facing the outer edge by means of the insulation element. This eliminates the need for complex procedures for insulating the contact element, such as folding down an end piece of the contact element.

A connection carrier described here is therefore characterized not only by its cost-effective manufacturability but also by the fact that it can be operated safely in a particularly simple manner, i.e., that creepage distances at the outer edges of the connection carrier can be prevented in a particularly simple manner, for example.

According to at least one aspect of the connection carrier, the connecting element projects laterally above the contact element, i.e., in at least one lateral direction. In particular, it is possible that the connecting element projects beyond the contact element in all lateral directions. This means, for example, that the connecting element extends slightly beyond the dimensions of the contact element in the lateral directions and thus allows a mounting tolerance when placing the contact element on the connecting element. The projection can be particularly small, as it does not have to be used to generate creepage distances. The projection is then, for example, between at least 50 μm and at most 300 μm. In extreme cases, the projection can be dispensed with completely.

According to at least one aspect of the connection carrier, the insulation element covers the connecting element on a connecting element cover surface facing away from the substrate. This means, for example, that the insulation element is drawn from the contact element cover surface over the contact element side surface onto the connecting element cover surface. In this way it is possible to completely enclose at least the contact element side surfaces facing the outer edges of the connection carrier in electrically insulating material. In this case, the top and sides of the contact element are covered by the insulation element, on the underside by the electrically insulating connecting element. In the region of the side surface of the contact element, for example, the insulation element and the connecting element adjoin each other directly and are joined together in a material-locking manner. This results in a complete encapsulation of the contact element in this area.

According to at least one aspect of the connection carrier, the insulation element covers the connecting element on a connecting element side surface facing the substrate side surface. This means that in this aspect, for example, the insulation element is guided from the contact element cover surface via the contact element side surface to the connecting element cover surface and from there to the connecting element side surface. The insulation element can extend over the specified distance without interruption. The fact that the insulation element also covers the connecting element on its side surface and is connected to the connecting element in a material-locking manner, for example, results in a further improved encapsulation of the contact element with electrically insulating material at least in the area of the outer edges of the connection carrier.

According to at least one aspect of the connection carrier, the insulation element is in direct contact with the substrate in places. This means that in this case, for example, the insulation element can be drawn from the contact element cover surface, over the contact element side surface to the connecting element cover surface and over the connecting element cover surface to the substrate top surface and/or to the substrate side surface and there be in direct contact with the substrate. In this design, for example, the connection carrier is covered by the insulation element along all its outer edges and creepage distances to and from the contact element are completely prevented from the outer edges of the connection carrier.

According to at least one aspect of the connection carrier, the central region of the substrate top surface is completely surrounded by the insulation element on the side, i.e., in the lateral directions. This means that the insulation element, which can be in direct contact with the substrate, for example, completely surrounds the central region and covers the substrate at its outer edges without interruption.

According to at least one aspect of the connection carrier, the connecting element and the contact element are curved in places in plan view. In particular, this means that the connecting element and the contact element are not designed as strips which are rectangular in plan view, for example, but rather have curved outer edges in plan view. With these curved outer edges, a particularly precise adaptation of the shape of the contact element or the contact elements of the connection carrier can be adapted to the requirements of the components that are to be fastened to the connection carrier and electrically connected.

According to at least one aspect of the connection carrier, the substrate has a reflectivity of at least 80%, in particular of at least 85%, for light, at least in the central region on the substrate top surface. The substrate exhibits said reflectivity preferably at a wavelength of at least 430 nm and at most 700 nm, in particular at a wavelength of 450 nm. The reflectivity can preferably be at least 90%. In other words, visible light incident perpendicular to the main extension plane on the substrate surface of the substrate, for example, in the central region, is reflected with a probability of at least 80%, preferably at least 85% and particularly preferably at least 90%. The substrate is thus highly reflective for visible light, especially for blue light. Such a highly reflective, in particular multilayer substrate can be produced cost-effectively and allows in particular the use of the connection carrier to form an optoelectronic component.

Further an optoelectronic component is specified. With the optoelectronic component described here, a connection carrier described here can be used in particular. This means that all the features disclosed for the connection carrier are also disclosed for the optoelectronic component and vice versa. The optoelectronic component is, for example, a so-called chip-on-board LED module or a so-called “light kernel”. Light emitting diode chips can then be used in the optoelectronic component, for example. Furthermore, it is possible that laser diode chips and/or photodetector chips can be used alternatively or additionally in the optoelectronic component.

According to at least one aspect of the optoelectronic component, the optoelectronic component comprises a connection carrier described here. Furthermore, the optoelectronic component described here comprises one, in particular at least two optoelectronic semiconductor chips, which can be, for example, of a similar type. This means, for example, that they can be semiconductor chips that are constructed in the same way within the framework of manufacturing tolerance. It is possible that the optoelectronic semiconductor chips are light emitting diode chips and/or photodiode chips and/or laser diode chips.

In particular, optoelectronic semiconductor chips can be so-called sapphire chips. These chips may, for example, comprise a support formed of sapphire and which is part of a growth substrate onto which a semiconductor layer sequence comprising an active region intended for radiation generation has been epitaxially deposited.

According to at least one aspect, the optoelectronic semiconductor chips are attached to the substrate in the central region on the substrate top surface. This means that the optoelectronic semiconductor chips are applied to the substrate in an area that is free of the connecting element, the contact element and the insulation element. For example, the semiconductor chips can be attached to the substrate in the central region by gluing or soldering, whereby there is no electrical connection between the substrate and the optoelectronic semiconductor chips. This can be achieved, for example, by the substrate top surface in the central region being electrically insulating and/or the optoelectronic semiconductor chips with their electrically insulating side, in particular a carrier made of sapphire, being attached to the top surface.

According to at least one aspect, the optoelectronic semiconductor chips are electrically conductively connected to the contact element. In particular, the optoelectronic semiconductor chips are electrically conductively connected to at least two contact elements of the connection carrier. For example, the optoelectronic component comprises a large number of optoelectronic semiconductor chips, at least some of which are connected in series. The series connection of optoelectronic semiconductor chips is then contacted by two contact elements of the connection carrier.

According to at least one aspect, an optoelectronic component is specified with a connection carrier according to one of the previous claims, and at least two optoelectronic semiconductor chips, where, the optoelectronic semiconductor chips are attached to the substrate in the central region on the substrate top surface, and the optoelectronic semiconductor chips are electrically conductively connected to the contact element.

According to at least one aspect of the optoelectronic component, the optoelectronic semiconductor chips are surrounded by a light-transmitting, electrically insulating envelope, the envelope being in direct contact with the substrate on its substrate top surface. For example, the envelope in the central region of the substrate top surface is in direct contact with the substrate. The envelope is in particular a potting body that is applied to the optoelectronic semiconductor chips. The potting body may comprise a matrix material into which particles of one or more materials are incorporated.

For example, particles of a fluorescent material are introduced into the matrix material which is designed to absorb part of the primary radiation emitted by the optoelectronic semiconductor chips during operation and to emit electromagnetic radiation from another wavelength range, for example, with longer wavelengths. In this way, mixed light, for example, white light, can be emitted from the optoelectronic component in operation. The matrix material can be, for example, a silicone material, an epoxy material or a silicone-epoxy hybrid material.

In addition to its optical properties, the envelope also serves to mechanically protect the optoelectronic semiconductor chips from external influences. In addition, the envelope is an electrically insulating component of the optoelectronic component, which can help to prevent creepage distances to the contact element of the connection carrier.

According to at least one aspect of the optoelectronic component, the envelope is in direct contact with the insulation element. For example, the insulation element on the side of the contact element and the connecting element facing the semiconductor chips is guided over these two components and covers the substrate top surface there. In this case, for example, the insulation element is formed with a lacquer, for example, a solder resist, which then completely surrounds the optoelectronic semiconductor chips. Furthermore, it is possible that the envelope is in direct contact with the substrate, the connecting element, the contact element and the insulation element. The envelope can then adhere particularly well to the connection carrier, as the adherence surface to the connection carrier is particularly large in this case.

According to at least one aspect of the optoelectronic component, an outer edge of the insulation element facing the optoelectronic semiconductor chips forms a stop edge for the envelope. In this case, for example, the insulation element is arranged on the contact element cover surface and does not extend to the connection layer on the side of the connection layer facing the optoelectronic semiconductor chips, but ends at the contact element cover surface. In this region, the insulation element then has an outer edge facing the semiconductor chips. The envelope material can then be selected with regard to its viscosity, for example, when applied to the optoelectronic semiconductor chips in such a way that it stops at the outer edge of the insulation element. In this case, it is advantageous not to need another element, for example, a surrounding dam, which fixes the envelope material in the central region of the substrate top surface, where the optoelectronic semiconductor chips are arranged.

According to at least one aspect of the optoelectronic component, the contact element is not freely accessible at any point apart from the contact points provided for contacting the component from the outside. In particular, it is possible in this case that no contact element of the connection carrier is freely accessible. In this case, the contact element or elements of the connection carrier are to a large extent completely covered by other components of the connection carrier and the optoelectronic component. For example, the contact element is completely covered by the insulation element and the envelope. For example, it is possible that the insulation element is in direct contact with the envelope and completely surrounds the envelope in lateral directions, i.e., laterally. In this way, creepage distances to the contact element of the optoelectronic component are completely eliminated. Only in the area of the contact points is the insulation element then opened. The contact points are preferably at least 1 mm from an outer edge of the connection carrier, which makes it possible to cover the area between a contact point and the outer edge with material of the insulation element.

In addition, a method for producing a connection carrier or an optoelectronic component is specified. The method can be used to produce the connection carriers described here and the optoelectronic components described here, i.e., all features disclosed for the connection carriers described here and the optoelectronic components described here are also disclosed for the method and vice versa.

According to at least one aspect of the method, an assembly comprising a plurality of substrates attached to each other is provided first. The assembly can be a panel or an endless roll, for example, which can later be separated into individual substrates or individual connection carriers. In the next process step, mounting openings and separating openings are created in the substrates of the assembly by punching. The punching of the mounting openings and the separating openings can be carried out advantageously in a common process step, so that these openings in the substrates can be produced particularly efficiently.

The separating openings, for example, extend trench-shaped between adjacent substrates without extending along the entire outer edge of a substrate. In this way, the separating openings serve, for example, as predetermined breaking points in a later processing step.

In a final processing step, the assembly along the separating openings is separated into a large number of substrates. This can take place, for example, after completion of the connection carrier or after completion of the optoelectronic component, so that it is separated to connection carriers or components.

The structuring of the elements mentioned as well as the insulation element can increase the production costs compared to known connection carriers, but this is more than compensated by reducing the effort involved in separating the connection carriers from the assembly of substrates, in which no special measures must be taken to avoid shunts between the contact elements and the substrate.

The optoelectronic component described here can be characterized by a particularly large light-emitting surface which is formed by the surface of the central region of the substrate top surface. For example, the light-emitting surface may have a diameter of at least 1.5 mm and at most 45 mm, in particular between at least 5 mm and at most 33 mm. In particular, the light-emitting surface has a diameter of approximately 9 mm, approximately 13 mm, approximately 19 mm or approximately 24 mm, with a tolerance of 1 mm each.

### BRIEF DESCRIPTION OF THE DRAWINGS

In the following, the connection carriers described here, the optoelectronic components described here and the methods described here are explained in more detail using embodiments and the corresponding figures.

FIGS. 1A, 1B and 1C show a first embodiment of a connection carrier using schematic illustrations;

FIGS. 2 and 3 show further embodiments of the connection carriers using schematic illustrations;

FIGS. 4A and 4B show an embodiment of an optoelectronic component using schematic illustrations; and

FIGS. 5A, 5B and 5C show an embodiment of a procedure using schematic illustrations.

Identical, similar or similar acting elements are provided with the same reference signs in the figures. The figures and the proportions of the elements shown in the figures are not to be regarded as true to scale. Rather, individual elements may be oversized to make them easier to display and/or understand.

### DETAILED DESCRIPTION OF ILLUSTRATIVE EMBODIMENTS

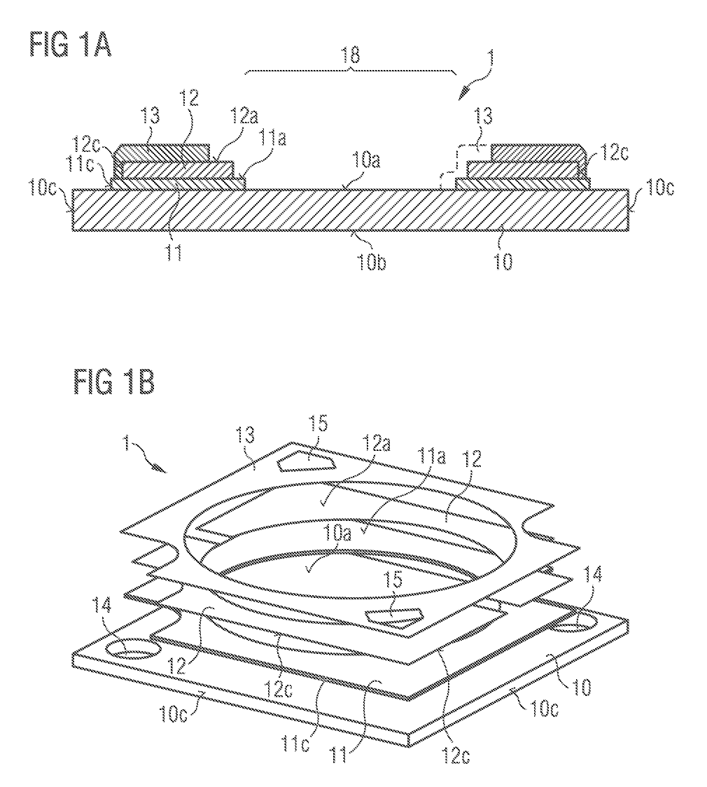

FIG. 1A shows a first embodiment of a connection carrier described here using a schematic sectional view. FIG. 1B shows the corresponding exploded view. FIG. 1C shows a schematic top view.

The connection carrier 1 comprises a substrate 10, which is, for example, a multi-layer carrier metal plate described here. Substrate 10 comprises a top surface 10a, a bottom surface 10b and side surfaces 10c, which connect the top surface 10a with the bottom surface 10b. Connecting element 11 is arranged on the substrate top surface 10a, which encloses a central region 18 in the form of a ring or frame (see FIGS. 1B and 1C, for example). Connecting element 11 is connected to substrate 10 in a material-locking manner.

Two contact elements 12 are applied to connecting element 11 on the connecting element cover surface 11a facing away from the substrate, which are connected in a material-locking manner to connecting element 11. The connecting element 11 projects beyond the contact elements 12 in the lateral directions, parallel to the main extension direction of the substrate top surface 10a of the substrate 10.

On the side facing away from the connecting element, the contact element cover surface 12a is formed, which is covered in places by insulation element 13. For example, the insulation element 13 and the contact element 12 are material-locked to each other. The insulation element 13 can also surround the central region 18 of the substrate top surface 10a in the form of a ring or frame.

The insulation element 13 is guided along the contact element cover surface 12a to the contact element side surface 12c. It covers the contact element side surface 12c completely and is in direct contact with connecting element 11 on connecting element cover surface 11a on the side facing the substrate side surface 10c. In the present case, the connecting element 11 also completely projects beyond the insulation element 13 at every point on the side or is flush with it.

By means of connecting element 11 and insulation element 13, contact element 12 is completely covered with electrically insulating material of connecting element 11 and insulation element 13 on the side facing the outer edge of connection carrier 1.

As can be seen from FIGS. 1B and 1C, for example, the connection carrier also includes mounting openings 14, which are arranged in opposing quadrants of substrate 10. The surroundings of the mounting openings 14 are free of the connecting element 11, the contact element 12 and the insulation element 13. However, it is also possible that the insulation element 13 in particular is guided to the outer edge of the substrate 10 and also completely encloses the mounting openings 14 in lateral directions.

The connection carrier 1 also includes contact points 15, which are arranged in the quadrants not occupied by the mounting openings 14. Insulation element 13 is not attached to these contact elements and contact element 12 is freely accessible and contactable there.

The connecting element 11, the contact element 12 and, where appropriate, the insulation element 13 may be structured by processes such as punching or a laser cutting process, so that they may have curved outer surfaces in particular. In the central region 18 of the substrate top surface 10a, for example, the diameter D1 between opposite edges of the connecting element 11 can be 17.9 mm in this case. For example, the diameter D2 between opposite edges of contact element 12 can be 18.7 mm and the diameter D3 between opposite edges of insulation element 13 can be 19.8 mm. The tolerance is, for example, 1 mm each.

In deviation from the embodiment shown in FIG. 1A, it is also possible that the insulation element 13 is guided to substrate 10 on the side of contact element 12 facing the central region 18 and connecting element 11. This is indicated in the right area of FIG. 1A by dashed lines. For example, if insulation element 13 is not designed as a film but as a coating, for example, by means of a solder resist, this is a possible variant of the course of the insulation element 13. In this case, insulation element 13 is white, for example, and can thus prevent optical impairment by contact element 12 or connecting element 11.

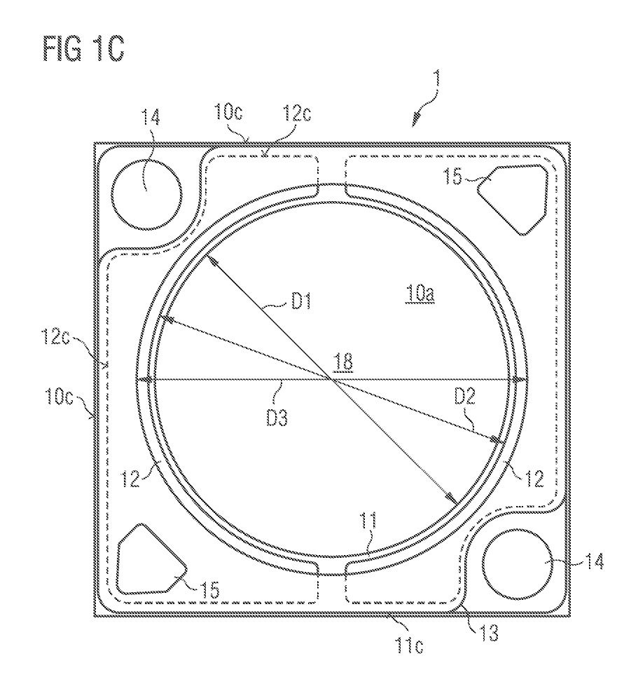

In connection with the schematic sectional representation of FIG. 2, a further embodiment of a connection carrier described here is explained in more detail.

FIG. 2 shows a connection carrier comprising substrate 10, which comprises substrate top surface 10a, substrate bottom surface 10b opposite to substrate top surface 10a and substrate side surface 10c. Furthermore, connection carrier 1 comprises connecting element 11, which is electrically insulating, contact element 12, which is electrically conductive, and insulation element 13, which is electrically insulating. The connecting element 11 is arranged on the substrate top surface 10a, the contact element 12 is arranged on the side of the connecting element 11 remote from the substrate 10, and the insulation element 13 is arranged on the side of the contact element 12 remote from the connecting element 11. The connecting element 11 projects laterally beyond the contact element 12. The substrate side surface 10c connects the substrate top surface 10a and the substrate bottom surface 10b. The insulation element 13 covers the contact element 12 on the contact element cover surface 12a facing away from the connecting element 11 and the contact element side surface 12c facing the substrate side surface 10c. The substrate top surface 10a is freely accessible in central region 18, and central region 18 is surrounded laterally by insulation element 13.

In contrast to the embodiment in FIG. 1A, in the embodiment in FIG. 2 the insulation element 13 is guided along the contact element cover surface 12a via the contact element side surface 12c from the connecting element cover surface 11a to the substrate top surface 10a. It is possible that the insulation element 13 is flush with the outer edge of the substrate 10 or that the substrate 10 projects laterally beyond the insulation element 13.

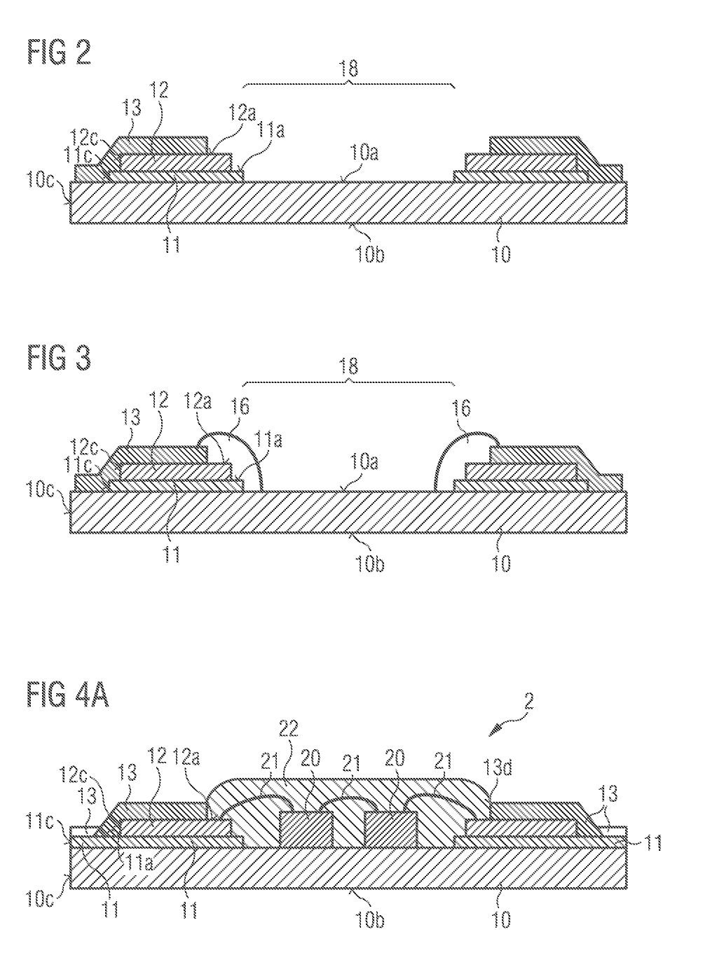

In connection with the schematic sectional representation of FIG. 3, a further embodiment of a connection carrier described here is explained in more detail. A connection carrier is shown with substrate 10, which comprises the substrate top surface 10a, the substrate bottom surface 10b opposite the substrate top surface 10a and the substrate side surface 10c. Furthermore, the connection carrier comprises connecting element 11, which is electrically insulating, contact element 12, which is electrically conductive, and insulation element 13, which is electrically insulating. The connecting element 11 is arranged on the substrate top surface 10a, the contact element 12 is arranged on the side of the connecting element 11 remote from the substrate 10, and the insulation element 13 is arranged on the side of the contact element 12 remote from the connecting element 11. The connecting element 11 projects laterally beyond the contact element 12. The substrate side surface 10c connects the substrate top surface 10a and the substrate bottom surface 10b. The insulation element 13 covers the contact element 12 on the contact element cover surface 12a facing away from the connecting element 11 and the contact element side surface 12c facing the substrate side surface 10c. The substrate top surface 10a is freely accessible in central region 18, and central region 18 is surrounded laterally by insulation element 13.

In addition to the embodiment of FIG. 2, in this embodiment a dam 16 is formed which surrounds the central region 18 in the form of a ring or frame. Dam 16 can be made of an electrically insulating material which, for example, has a color. Dam 16, for example, can be formed with a silicone material filled with pigments so that dam 16 appears colored, radiation-absorbing or white. For example, the dam is formed with a titanium dioxide filled silicone and therefore appears white.

Alternatively, it is possible that dam 16 is formed with material of insulation element 13.

In any case, the side of the contact elements 12 facing the central region 18 is also surrounded by electrically insulating material in this embodiment. Only to allow the connection of semiconductor chips, there are recesses in the dam or insulation element which are not shown in FIG. 3.

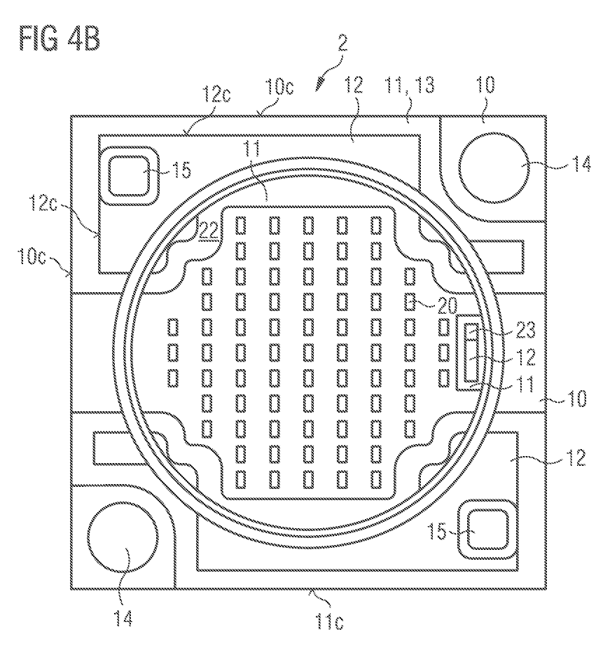

Dam 16 can also be used to enclose a covering material 22, see, for example, FIG. 4A.

In connection with the schematic illustrations of FIGS. 4A and 4B, an optoelectronic component described here is explained in more detail according to a first embodiment. Each connection carrier 1 described here can be used for the optoelectronic component.

The connection carrier 1 comprises substrate 10, which comprises the substrate top surface 10a, the substrate bottom surface 10b opposite the substrate top surface 10a and the substrate side surface 10c. Furthermore, the connection carrier has the connecting element 11, which is electrically insulating, the contact element 12, which is electrically conductive, and the insulation element 13, which is electrically insulating. As shown in the embodiments of FIGS. 1, 2 and 3, connecting element 11 is arranged on the substrate top surface 10a, contact element 12 is arranged on the side of connecting element 11 facing away from substrate 10, and insulation element 13 is arranged on the side of contact element 12 facing away from connecting element 11. The connecting element 11 projects laterally beyond the contact element 12. The substrate side surface 10c connects the substrate top surface 10a and the substrate bottom surface 10b.

The insulation element 13 covers the contact element 12 on the contact element cover surface 12a facing away from the connecting element 11 and the contact element side surface 12c facing the substrate side surface 10c. The substrate top surface 10a is freely accessible in central region 18 and central region 18 is surrounded laterally by insulation element 13. In the example in FIGS. 4A and 4B, a connection carrier is used in which the connecting element 11 and the insulation element 13 each extend to the outer edge of substrate 10 so that the side surfaces of the insulation element 13, the connecting element 11 and the substrate 10 facing the outer edge of the connection carrier are flush with each other.

The optoelectronic component also comprises a large number of optoelectronic semiconductor chips 20, for example, light emitting diode chips. The semiconductor chips 20 are connected to each other at least partially in series via wire contacts 11, which are electrically conductively connected to contact elements 12. Furthermore, the optoelectronic semiconductor chips 20 are surrounded by an envelope 22, which can be a potting material filled with a converter, for example.

The outer edge 13d of the insulation element 13 facing the semiconductor chips 22 serves as a stop edge for the envelope material 22.

As can be seen from the top view of FIG. 4B, the optoelectronic component can also comprise an ESD protection element 23, which, for example, is an ESD protection diode connected anti-parallel to the optoelectronic semiconductor chips 20 connected in series. A further contact element 12 is provided for connecting the ESD protection element 23, which is attached to substrate 10 via a further connecting element 11. Alternatively, the contact elements 12 can be formed so that no further connecting element 11 is required to place and contact the ESD protection element 23. This is possible, for example, with the connection carrier of FIGS. 1A to 1C, in which the two contact elements 12 have a very small distance to each other at two points, so that, for example, a wire contact of the ESD protective element 23 from a contact element to the adjacent contact element is possible.

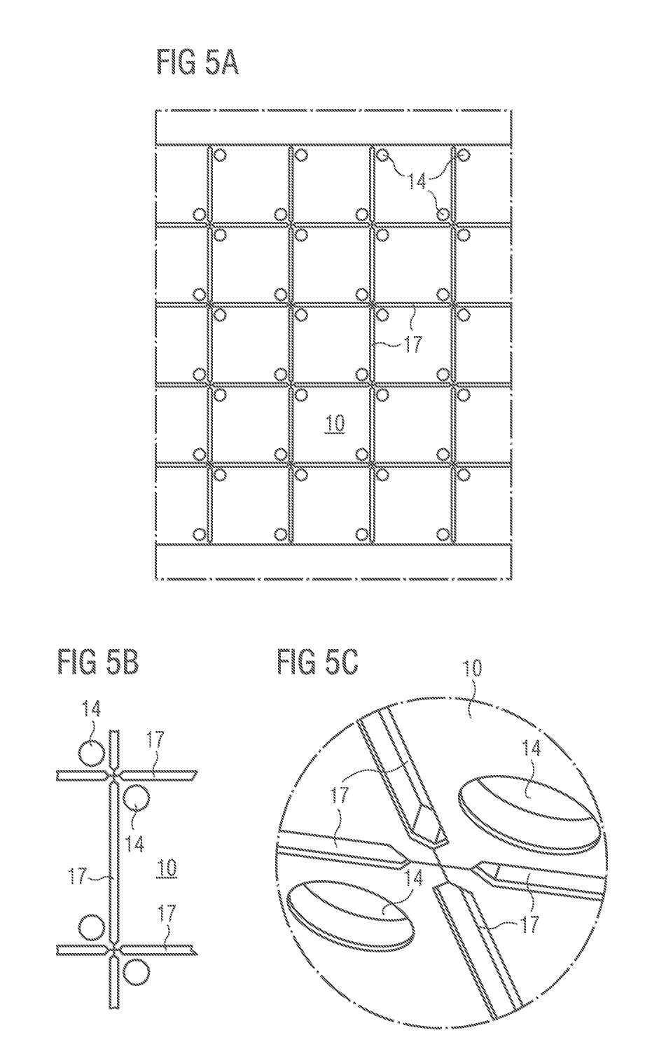

In connection with FIGS. 5A, 5B and 5C, an embodiment of a method described here is explained in more detail. In the method, an assembly comprising a plurality of substrates 10 is provided. For example, the assembly is a panel or an endless roll. Mounting openings 14 and separating openings 17 are produced in the substrates by punching. For example, the mounting openings 14 and the separating openings 17 can be pre-punched in the same work step. The mounting openings 14 are used, for example, to accommodate fastening elements such as screws, rivets or bolts.

The separating openings extend over most of the outer edge of each substrate 10 without extending completely along the outer edge. In this way, the substrates 10 are connected at the corners.

After the connection carrier or the optoelectronic component has been manufactured, the substrates can be separated from each other by separating the arrangement along the separating openings.

In particular, the connection carriers described here as well as the components described here are characterized by a particularly cost-effective manufacturability. A further advantage of the connection carriers described here and of the components described here is that they can be used particularly safely on their outer edges to avoid creepage distances.

The invention is not limited to the description based on the embodiments. Rather, the invention includes each new feature and each combination of features, which includes in particular each combination of features in the patent claims, even if this feature or this combination itself is not explicitly mentioned in the patent claims or embodiments.

1-14. (canceled)

15. A connection carrier comprising:
a substrate comprising:
a substrate top surface;
a substrate bottom surface opposite the substrate top surface; and
a substrate side surface,
an electrically insulating connecting element;
an electrically conductive contact element; and
an insulation element,
wherein the connecting element is arranged on the substrate top surface,
wherein the contact element is arranged on the connecting element opposite the substrate,
wherein the insulation element is arranged on the contact element opposite the connecting element,
wherein the substrate side surface connects the substrate top surface and the substrate bottom surface,
wherein the insulation element covers the contact element on a contact element cover surface facing away from the connecting element and on a contact element side surface facing the substrate side surface,
wherein the substrate top surface is freely accessible in a central region,
wherein the central region is surrounded laterally by the insulation element, and
wherein the insulation element covers the connecting element on the connecting element side surface facing the substrate side surface.

16. The connection carrier according to claim 15, wherein the connecting element projects laterally beyond the contact element.

17. The connection carrier according to claim 15, wherein the insulation element covers the connecting element on a connecting element cover surface facing away from the substrate.

18. The connection carrier according to claim 15, wherein the substrate comprises a base body which comprises aluminum.

19. The connection carrier according to claim 15, wherein the insulation element is in direct contact with the substrate in places.

20. The connection carrier according to claim 15, wherein the central region is completely surrounded laterally by the insulation element.

21. The connection carrier according to claim 15, wherein the connecting element and the contact element are curved in places in plan view.

22. The connection carrier according to claim 15, wherein the substrate has a reflectivity of at least 80 for light at least in the central region on the substrate top surface.

23. An optoelectronic component comprising:
the connection carrier according to claim 15; and
at least two optoelectronic semiconductor chips,
wherein the optoelectronic semiconductor chips are mounted in the central region on the substrate top surface, and
wherein the optoelectronic semiconductor chips are electrically conductively connected to the contact element.

24. The optoelectronic component according to claim 23, wherein the optoelectronic semiconductor chips are surrounded by a translucent, electrically insulating envelope, the envelope being in direct contact with the substrate on the substrate top surface.

25. An optoelectronic component according to claim 24, wherein the envelope is in direct contact with the insulation element.

26. The optoelectronic component according to claim 25, wherein an insulation element outer edge facing the optoelectronic semiconductor chips serves as a stop edge for the envelope.

27. The optoelectronic component according to claim 23, wherein the contact element is not freely accessible at any point apart from contact points provided for contacting from an outside.

28. A method for producing a connection carrier, wherein the connection carrier comprises a substrate having a substrate top surface, a substrate bottom surface opposite the substrate top surface and a substrate side surface, an electrically insulating connecting element, an electrically conductive contact element, and an insulation element, the method comprising:
providing an assembly comprising a plurality of the substrates attached to each other;
producing mounting and separating openings in the substrates by punching; and
separating the assembly along the separating openings.

29. A method for producing an optoelectronic component, the method comprising:
producing the connection carrier according to claim 28;
providing at least two optoelectronic semiconductor chips;
mounting the optoelectronic semiconductor chips in a central region on the substrate top surface of the substrate; and
conductively connecting the optoelectronic semiconductor chips to the contact element.
